(19) United States
(12) Patent Application Publication
(10) Pub. No.: US 2026/0123434 A1
(43) Pub. Date: Apr. 30, 2026

(54) GLASS SUBSTRATE, SEMICONDUCTOR PACKAGE INCLUDING GLASS SUBSTRATE, AND METHOD FOR MANUFACTURING THE SAME

(71) Applicant: Samsung Electronics Co., Ltd., Suwon-si (KR)

(72) Inventor: Junghoon KANG, Suwon-si (KR)

(73) Assignee: Samsung Electronics Co., Ltd., Suwon-si (KR)

(21) Appl. No.: 19/211,405

(22) Filed: May 19, 2025

(30) Foreign Application Priority Data
Oct. 24, 2024 (KR) 10-2024-0146987

(51) Int. Cl. H01L 23/00; H01L 21/48; H01L 21/56; H01L 23/15; H01L 23/31; H01L 23/498

(52) U.S. Cl. CPC H10W 42/121; H10W 70/05; H10W 70/093; H10W 70/095; H10W 70/635; H10W 70/685; H10W 70/692; H10W 74/016; H10W 74/117; H10W 90/701; H10W 70/655; H10W 90/724

(57) ABSTRACT

A glass substrate may include a first redistribution structure, a core layer on the first redistribution structure, and a second redistribution structure on the core layer. The core layer may include a glass core and a dummy structure surrounding side surfaces of the glass core. The dummy structure may include a metal material, an organic material, or both the metal material and the organic material.

### CROSS-REFERENCE TO RELATED APPLICATION

This application claims priority to and the benefit of Korean Patent Application No. 10-2024-0146987 filed at the Korean Intellectual Property Office on Oct. 24, 2024, the entire contents of which are incorporated herein by reference.

### BACKGROUND

### (a) Field

The present disclosure relates to a glass substrate, a semiconductor package including the glass substrate, and/or a method for manufacturing the same.

### (b) Description of the Related Art

In response to a demand for miniaturization of a semiconductor package, a glass substrate capable of forming fine-spaced inputs/outputs (I/Os) is being adopted as a product replacing an organic substrate with general-spaced I/Os. Using the glass substrate may reduce a thickness of the semiconductor package by not using an interposer between the organic substrate and a semiconductor die, and may improve power integrity (PI) and signal integrity (SI) of the semiconductor package.

The semiconductor package to which the glass substrate is applied may be manufactured by performing an individualization process in which semiconductor dies are mounted and molded on a glass wafer (or a glass panel) and then are cut into individual semiconductor package units using a laser. However, because glass of the glass substrate typically may be a brittle material and may have a property of being easily destroyed, a microcrack may occur around a portion cut by the laser during the individualization process, or a heat affected zone (HAZ) on which a stress acts may be generated. This may degrade a mechanical characteristic of the glass substrate.

### SUMMARY

A semiconductor package, in which a dummy structure including at least one of a metal and an organic dielectric is along a scribe lane of a glass wafer (or a glass panel), may be provided.

A glass substrate according to an embodiment of the present disclosure may include a first redistribution structure; a core layer on the first redistribution structure, the core layer including a glass core and a dummy structure surrounding side surfaces of the glass core, and the dummy structure including a metal material, an organic material, or both the metal material and the organic material; and a second redistribution structure on the core layer.

A semiconductor package according to an embodiment may include a glass substrate including a first redistribution structure, a core layer on the first redistribution structure, and a second redistribution structure on the core layer; a plurality of semiconductor dies on the glass substrate; and a molding material covering the plurality of semiconductor dies on the glass substrate. The core layer may include a glass core, a plurality of through glass vias penetrating the glass core, and a dummy structure surrounding side surfaces of the glass core. The dummy structure may include a metal, a first organic dielectric, or both the metal and the first organic dielectric.

A method for manufacturing a semiconductor package according to an embodiment may include providing a glass wafer including a plurality of glass cores and a scribe lane surrounding side surfaces of each of the plurality of glass cores; forming a plurality of holes recessed from a first surface of the glass wafer within each of the plurality of glass cores and forming a trench recessed from the first surface of the glass wafer along the scribe lane; forming a plurality of through glass vias, the forming the plurality of through glass vias including filling the plurality of holes with a conductive material; forming a dummy structure in the trench, the dummy structure including a metal, an organic dielectric, or both the metal and the organic dielectric; forming an upper redistribution structure on the first surface of the glass wafer; mounting a plurality of semiconductor dies on the upper redistribution structure; providing a molding material on the plurality of semiconductor dies on the upper redistribution structure; thinning a second surface of the glass wafer to expose the plurality of through glass vias and the dummy structure, wherein the second surface of the glass wafer is opposite the first surface of the glass wafer; forming a lower redistribution structure on the second surface of the glass wafer after the thinning the second surface of the glass wafer; and forming an individual semiconductor package by cutting the molding material, the upper redistribution structure, the dummy structure, and the lower redistribution structure.

A method of manufacturing a glass substrate may include forming an upper redistribution structure on a first surface of a wafer, wherein the wafer may include a glass core, a plurality of through-glass vias, and a dummy structure surrounding the plurality of through-glass vias, the dummy structure including a metal material, an organic material, or both the metal material and the organic material, and the wafer may include a scribe lane surrounding the glass core, the plurality of through-glass vias, and the dummy structure; thinning a second surface of the wafer to expose the plurality of through-glass vias; forming a lower redistribution structure on the second surface of the wafer after the thinning the second surface of the wafer; and cutting a core layer from the wafer by cutting through the scribe lane, wherein the core layer may include the glass core, the plurality of through-glass vias, and the dummy structure.

In some embodiments, the dummy structure may conformally extend along the side surfaces of the glass core.

In some embodiments, the dummy structure may be exposed to an outside after the cutting the core layer from the wafer.

In some embodiments, the second redistribution structure may cover an upper surface of the glass core and an upper surface of the dummy structure.

In some embodiments, the dummy structure may include a first structure including the metal material and a second structure including the organic material.

In some embodiments, the organic material may include polyimide (PI), Ajinomoto Build-up Film (ABF), a photoimageable dielectric (PID), or an epoxy molding compound (EMC).

Because a dummy structure including at least one of a metal and an organic dielectric is formed along a scribe lane, the dummy structure may be cut when cutting is performed along the scribe lane so that it may be possible to limit and/or prevent the occurrence of a microcrack around a cutting portion and formation of a heat affected zone (HAZ) on which a stress acts.

The dummy structure may be disposed along side surfaces of a glass core, so that rigidity of a glass substrate is reinforced.

The metal material included in the dummy structure may be exposed to the outside so that heat generated within a semiconductor package is discharged to the outside through the dummy structure. Thus, a heat dissipation characteristic of the semiconductor package may be improved.

### BRIEF DESCRIPTION OF THE DRAWINGS

FIG. 1 is a cross-sectional view showing a semiconductor package of an embodiment.

FIG. 2 is a plan view of a core layer of the semiconductor package of FIG. 1 cut along a line A-A.

FIGS. 3 to 23 are cross-sectional views showing a method for manufacturing the semiconductor package of FIG. 1.

FIG. 24 is a cross-sectional view showing a semiconductor package of an embodiment.

FIG. 25 is a plan view of a core layer of the semiconductor package of FIG. 24 cut along a line B-B.

FIG. 26 is a cross-sectional view showing a semiconductor package of an embodiment.

FIG. 27 is a plan view of a core layer of the semiconductor package of FIG. 26 cut along a line C-C.

FIG. 28 is a cross-sectional view showing a semiconductor package.

FIG. 29 is a plan view of a core layer of the semiconductor package of FIG. 28 cut along lines D-D and E-E.

FIG. 30 is a cross-sectional view showing a semiconductor package of an embodiment.

### DETAILED DESCRIPTION

Embodiments of the present disclosure will be described more fully hereinafter with reference to the accompanying drawings so that those skilled in the art could easily implement the embodiments. The present disclosure may be modified in various ways, all without departing from the spirit or scope of the present disclosure.

In order to clearly describe the present disclosure, parts or portions that are irrelevant to the description are omitted, and identical or similar constituent elements throughout the specification are denoted by the same reference numerals.

In the drawings, a size and a thickness of each element are arbitrarily illustrated for ease of description, and the present disclosure is not necessarily limited to those illustrated in the drawings.

Throughout the specification, when a part is “connected” to another part, it includes not only a case where the part is “directly connected” but also a case where the part is “indirectly connected” with another part in between. Unless explicitly stated to the contrary, the word “comprise” and variations such as “comprises” and “comprising” should be understood to imply the inclusion of stated elements but not the exclusion of any other elements.

It should be understood that when an element such as a layer, a film, a region, or a plate is referred to as being “on” or “above” another element, it may be directly on the other element, or an intervening element may also be present. In contrast, when an element is referred to as being “directly on” another element, there is no intervening element present. Further, in the specification, the word “on” or “above” means disposed on or below a referenced part, and does not necessarily mean disposed on the upper side of the referenced part based on a gravitational direction.

Throughout the specification, the phrase “in a plan view” or “on a plane” may mean when an object portion is viewed from above, and the phrase “in a cross-sectional view” or “on a cross-section” may mean when a cross-section taken by vertically cutting an object portion is viewed from the side.

Hereinafter, a semiconductor package (100) 100A, 100B, 100C, 100D, and 100E according to an embodiment including the glass substrate (or a glass interposer) GS, and a method for manufacturing the same will be described with reference to the drawings.

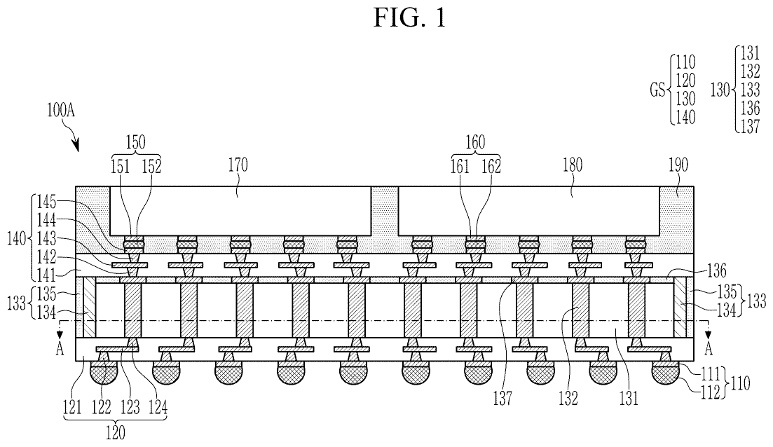

FIG. 1 is a cross-sectional view of an embodiment of a semiconductor package 100A.

Referring to FIG. 1, the semiconductor package 100A may include the glass substrate GS, a first bump structure 150, a second bump structure 160, a first semiconductor die 170, a second semiconductor die 180, and a molding material 190. In an embodiment, the semiconductor package 100A may include a 2.5D semiconductor package. In the 2.5D semiconductor package, the first semiconductor die 170 and the second semiconductor die 180 may be disposed above the glass substrate GS, and the glass substrate GS may electrically connect the first semiconductor die 170 to the second semiconductor die 180 and may electrically connect the first semiconductor die 170 and the second semiconductor die 180 to an external device. In an embodiment, the semiconductor package 100A may be manufactured based on a fan-out wafer level package (FOWLP) technology or a fan-out panel level package (FOPLP) technology.

The glass substrate GS may include an external connection structure 110, a lower redistribution structure (or a first redistribution structure) 120, a core layer 130, and an upper redistribution structure (or a second redistribution structure) 140.

The external connection structure 110 may be disposed on a lower surface of the lower redistribution structure 120. The external connection structure 110 may include connection pads 111 and external connection members 112. Each of the connection pads 111 may electrically connect a first via 122 among first vias 122 of the lower redistribution structure 120 corresponding to each of the connection pads 111 to an external connection member 112 among the external connection members 112 corresponding to each of the connection pads 111. Each of the external connection members 112 may be disposed below a connection pad 111 among the connection pads 111 corresponding to each of the external connection members 112, and may be electrically connected to the connection pad 111 among the connection pads 111 corresponding to each of the external connection members 112. The external connection members 112 may electrically connect the semiconductor package 100A to an external device (not shown).

The lower redistribution structure 120 may be disposed on the external connection structure 110. The lower redistribution structure 120 may include a first dielectric 121 and first circuit wires within the first dielectric 121. The first circuit wires may include the first vias 122, conductive lines 123, and second vias 124.

The first dielectric 121 may protect and insulate the first vias 122, the conductive lines 123, and the second vias 124. The core layer 130 may be disposed on an upper surface of the first dielectric 121. The external connection structure 110 may be disposed on a lower surface of the first dielectric 121.

The first vias 122, the conductive lines 123, and the second vias 124 may be sequentially disposed from below, and may form signal, ground, and electric power routing paths. The conductive lines 123 may extend in a horizontal direction within the first dielectric 121. The first vias 122 and the second vias 124 may extend in a vertical direction within the first dielectric 121. In another embodiment, the lower redistribution structure 120 including fewer or more conductive lines and fewer or more vias may be included within the scope of the present disclosure.

The core layer 130 may be disposed on the lower redistribution structure 120. The core layer 130 may include a glass core 131, through glass vias (TGVs) 132, a dummy structure 133, an insulating layer 136, and conductive pads 137. A finer circuit pattern may be formed on the glass core 131 using a glass material compared with a polymer material conventionally used as a core of an organic substrate. Therefore, if the semiconductor package is manufactured using the glass core 131, an interposer used to connect a high performance semiconductor die with fine-spaced I/Os and an organic substrate with general-spaced I/Os in a conventional semiconductor package may not be used, so that a size of the semiconductor package in a vertical direction is reduced. In an embodiment, the glass core 131 may include borosilicate glass, quartz, or non-alkali glass.

The through glass vias (TGVs) 132 may be disposed within the glass core 131. The through glass vias (TGVs) 132 may penetrate the glass core 131. Side surfaces of the through glass vias (TGVs) 132 may be surrounded by the glass core 131. Each of the through glass vias (TGVs) 132 may be disposed between a second via 124 among the second vias 124 of the lower redistribution structure 120 corresponding to each of the through glass vias (TGVs) 132 and a conductive pad 137 among the conductive pads 137 corresponding to each of the through glass vias (TGVs) 132. Each of the through glass vias (TGVs) 132 may electrically connect the conductive pad 137 among the conductive pads 137 corresponding to each of the through glass vias (TGVs) 132 to the second via 124 among the second vias 124 of the lower redistribution structure 120 corresponding to each of the through glass vias (TGVs) 132.

The dummy structure 133 may be disposed next to the glass core 131 and next to the insulating layer 136. The dummy structure 133 may be disposed around the glass core 131 and around the insulating layer 136. The dummy structure 133 may surround side surfaces of the glass core 131 and side surfaces of the insulating layer 136. The dummy structure 133 may cover and protect the side surfaces of the glass core 131 and the side surfaces of the insulating layer 136. The dummy structure 133 may be exposed to the outside of the semiconductor package 100A. The dummy structure 133 may be electrically separated from the first semiconductor die 170, the second semiconductor die 180, and other components within the semiconductor package 100A. Because the dummy structure 133 is disposed along the side surfaces of the glass core 131, rigidity of the glass substrate GS may be reinforced.

The dummy structure 133 may include at least one of a metal material and an organic material. The dummy structure 133 may include a first structure 134 and a second structure 135. The first structure 134 may include a metal. The first structure 134 may include inner side surfaces and outer side surfaces. The inner side surfaces of the first structure 134 may cover the side surfaces of the glass core 131. The second structure 135 may include a first organic dielectric. In an embodiment, the first organic dielectric may include polyimide (PI), Ajinomoto Build-up Film (ABF), a photoimageable dielectric (PID), or an epoxy molding compound (EMC). The second structure 135 may cover the outer side surfaces of the first structure 134. The second structure 135 may be exposed to the outside of the semiconductor package 100A. An upper surface of the first structure 134 may have the same level as that of an upper surface of the insulating layer 136, and may have the same level as those of upper surfaces of the conductive pads 137. An upper surface of the second structure 135 may have the same level as that of the upper surface of the insulating layer 136, and may have the same level as those of the upper surfaces of the conductive pads 137. A lower surface of the first structure 134 may have the same level as that of a lower surface of the glass core 131. A lower surface of the second structure 135 may have the same level as that of the lower surface of the glass core 131.

The insulating layer 136 may be disposed between the glass core 131 and the upper redistribution structure 140. The insulating layer 136 may include a first organic dielectric. In an embodiment, the first organic dielectric may include polyimide (PI), Ajinomoto Build-up Film (ABF), a photoimageable dielectric (PID), or an epoxy molding compound (EMC). The first organic dielectric of the insulating layer 136 may be the same material as that of the first organic dielectric of the second structure 135. The conductive pads 137 may be disposed between the glass core 131 and the upper redistribution structure 140. The conductive pads 137 may penetrate the insulating layer 136. Each of the conductive pads 137 may be disposed between a through glass via (TGV) 132 among the through glass vias (TGVs) 132 corresponding to each of the conductive pads 137 and a first via 142 among first vias 142 of the upper redistribution structure 140 corresponding to each of the conductive pads 137. Each of the conductive pads 137 may electrically connect the first via 142 among the first vias 142 of the upper redistribution structure 140 corresponding to each of the conductive pads 137 to the through glass via (TGV) 132 among the through glass vias (TGVs) 132 corresponding to each of the conductive pads 137.

The upper redistribution structure 140 may be disposed on the core layer 130. The upper redistribution structure 140 may cover an upper surface of the dummy structure 133, the upper surface of the insulating layer 136, and the upper surfaces of the conductive pads 137. The upper redistribution structure 140 may include a second dielectric 141, second circuit wires within the second dielectric 141, and bonding pads 145 on the second dielectric 141. The second circuit wires may include the first vias 142, conductive lines 143, and second vias 144.

The second dielectric 141 may protect and insulate the first vias 142, the conductive lines 143, and the second vias 144. The first bump structure 150, the second bump structure 160, and the molding material 190 may be disposed above an upper surface of the second dielectric 141. The dummy structure 133, the insulating layer 136, and the conductive pads 137 may be disposed on a lower surface of the second dielectric 141. The second dielectric 141 may be a second organic dielectric. In an embodiment, the second organic dielectric may include a photoimageable dielectric (PID). The second organic dielectric of the upper redistribution structure 140 may be a different material from that of the first organic dielectric of the insulating layer 136.

The first vias 142, the conductive lines 143, the second vias 144, and the bonding pads 145 may be sequentially disposed from below, and may form a signal routing path, a ground routing path, and an electric power routing path. The conductive lines 143 may extend in a horizontal direction within the second dielectric 141. The first vias 142 and the second vias 144 may extend in a vertical direction within the second dielectric 141. In another embodiment, the upper redistribution structure 140 including fewer or more conductive lines, fewer or more vias, and fewer or more bonding pads may be included within the scope of the present disclosure.

First bump structures 150 may be disposed between the glass substrate GS and the first semiconductor die 170. In an embodiment, each of the first bump structures 150 may include a microbump. Each of the first bump structures 150 may include a first connection pad 151 and a first solder 152. The first connection pad 151 may be disposed between a wire among wires of the first semiconductor die 170 corresponding to the first connection pad 151 and a first solder 152 among first solders 152 corresponding to the first connection pad 151. The first connection pad 151 may electrically connect the wire among the wires of the first semiconductor die 170 corresponding to the first connection pad 151 to the first solder 152 among the first solders 152 corresponding to the first connection pad 151. In an embodiment, the first connection pad 151 may include at least one of copper, aluminum, silver, tin, gold, nickel, lead, titanium, and an alloy thereof. The first solder 152 may be disposed between a bonding pad 145 among the bonding pads 145 of the upper redistribution structure 140 corresponding to the first solder 152 and a first connection pad 151 among first connection pads 151 corresponding to the first solder 152. The first solder 152 may electrically connect the first connection pad 151 among the first connection pads 151 corresponding to the first solder 152 to the bonding pad 145 among the bonding pads 145 corresponding to the first solder 152. In an embodiment, the first solder 152 may include at least one of tin, silver, lead, nickel, copper, and an alloy thereof.

Second bump structures 160 may be disposed between the glass substrate GS and the second semiconductor die 180. In an embodiment, the second bump structures 160 may include a microbump. Each of the second bump structures 160 may include a second connection pad 161 and a second solder 162. The second connection pad 161 may be disposed between a wire among wires of the second semiconductor die 180 corresponding to the second connection pad 161 and a second solder 162 among second solders 162 corresponding to the second connection pad 161. The second connection pad 161 may electrically connect the wire among the wires of the second semiconductor die 180 corresponding to the second connection pad 161 to the second solder 162 among the second solders 162 corresponding to the second connection pad 161. In an embodiment, the second connection pad 161 may include at least one of copper, aluminum, silver, tin, gold, nickel, lead, titanium, and an alloy thereof. The second solder 162 may be disposed between a bonding pad 145 among the bonding pads 145 of the upper redistribution structure 140 corresponding to the second solder 162 and a second connection pad 161 among second connection pads 161 corresponding to the second solder 162. The second solder 162 may electrically connect the second connection pad 161 among the second connection pads 161 corresponding to the second solder 162 to the bonding pad 145 among the bonding pads 145 corresponding to the second solder 162. In an embodiment, the second solder 162 may include at least one of tin, silver, lead, nickel, copper, and an alloy thereof.

The first semiconductor die 170 may be disposed above the glass substrate GS. The first semiconductor die 170 may be disposed side by side with the second semiconductor die 180. The first semiconductor die 170 may be disposed next to the second semiconductor die 180. In an embodiment, the first semiconductor die 170 may include a logic die. In an embodiment, the first semiconductor die 170 may include an application processor (AP). In an embodiment, the first semiconductor die 170 may include at least one of a central processing unit (CPU) and a graphics processing unit (GPU).

The second semiconductor die 180 may be disposed above the glass substrate GS. The second semiconductor die 180 may be disposed side by side with the first semiconductor die 170. The second semiconductor die 180 may be disposed next to the first semiconductor die 170. In an embodiment, the second semiconductor die 180 may include a memory die. In an embodiment, the second semiconductor die 180 may be a high bandwidth memory (HBM).

The first semiconductor die 170 and the second semiconductor die 180 may be directly disposed above the glass substrate GS without an interposer, and the semiconductor package 100A may not include the interposer. The semiconductor package 100A may have a reduced size in a vertical direction, so that lengths of a signal transfer path and an electric power transfer path within the semiconductor package 100A are reduced. Thus, power integrity (PI) and signal integrity (SI) of the semiconductor package 100A may be improved.

The molding material 190 may be disposed on the glass substrate GS. The molding material 190 may cover the first bump structures 150, the second bump structures 160, the first semiconductor die 170, and the second semiconductor die 180.

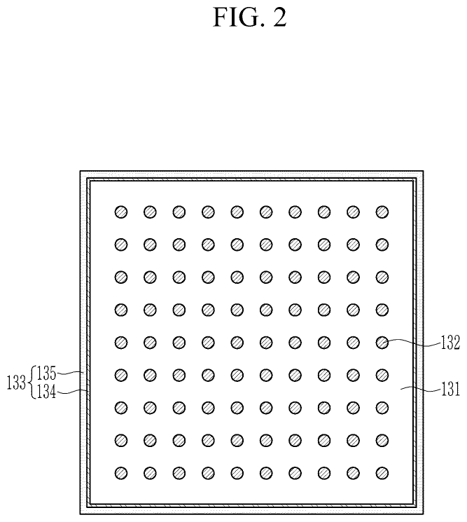

FIG. 2 is a plan view of the core layer 130 of the semiconductor package 100A of FIG. 1 cut along a line A-A.

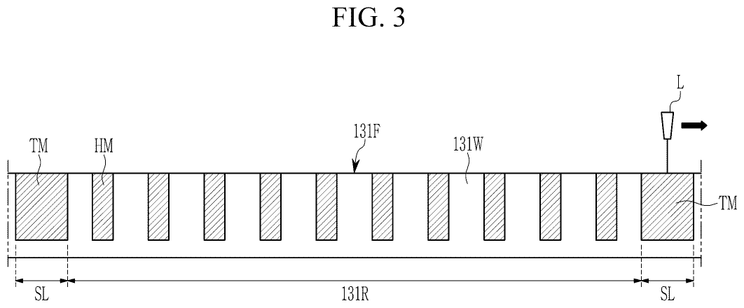

Referring to FIG. 2, the core layer 130 may include the glass core 131, the through glass vias (TGVs) 132, and the dummy structure 133. The through glass vias (TGVs) 132 may penetrate the glass core 131, and may be surrounded by the glass core 131. The dummy structure 133 may surround side surfaces of the glass core 131. The dummy structure 133 may be disposed at a region of a scribe lane SL (refer to FIG. 3) around the glass core 131. The dummy structure 133 may conformally extend along the side surfaces of the glass core 131. The dummy structure 133 may continuously extend along the side surfaces of the glass core 131. In an embodiment, the dummy structure 133 may have a quadrangular frame shape. In another embodiment, the core layer 130 including fewer or more through glass vias may be included within the scope of the present disclosure.

The dummy structure 133 may include the first structure 134 and the second structure 135. The first structure 134 may conformally extend along the side surfaces of the glass core 131. The first structure 134 may continuously extend along the side surfaces of the glass core 131. The first structure 134 may include a metal, and the first structure 134 including the metal may serve to limit and/or prevent moisture from penetrating into the glass core 131. The second structure 135 may conformally extend along side surfaces of the first structure 134. The second structure 135 may continuously extend along the side surfaces of the first structure 134. The second structure 135 may include a first organic dielectric, and the second structure 135 including the first organic dielectric may serve to limit and/or prevent a microcrack from occurring around a cutting portion when the second structure 135 is cut.

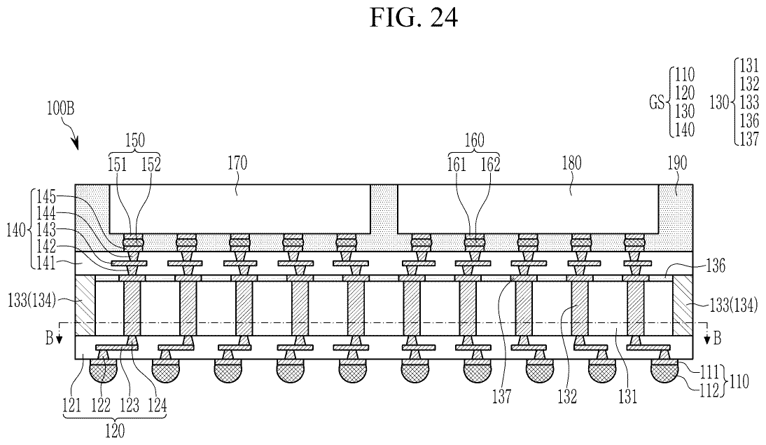

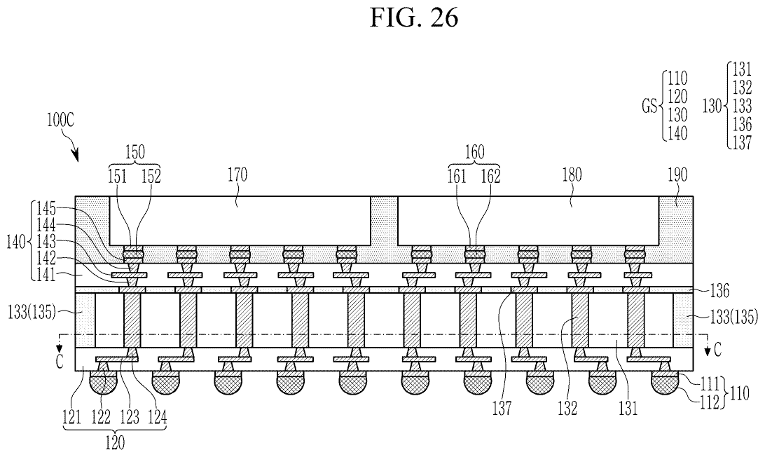

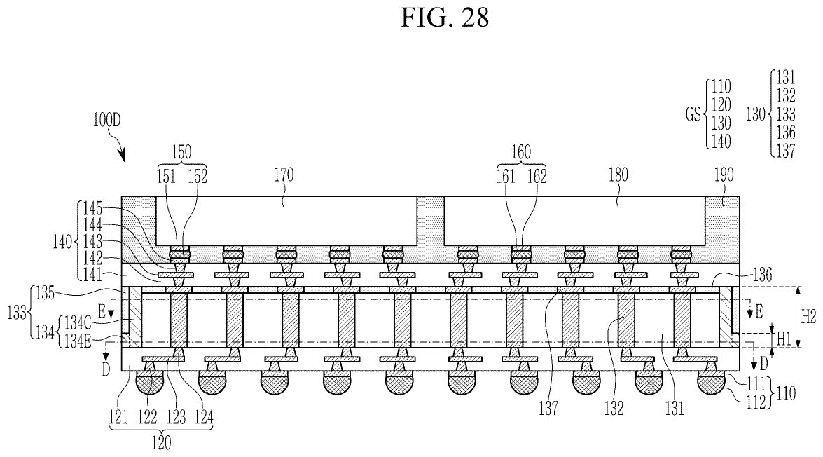

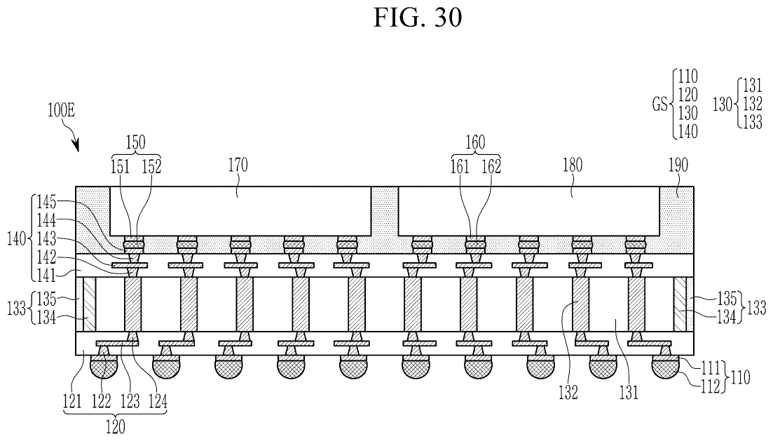

FIGS. 3 to 23 are cross-sectional views showing a method for manufacturing the semiconductor package 100A of FIG. 1. The method for manufacturing the semiconductor package 100A of FIG. 1 of FIGS. 3 to 23 may be applied to a method for manufacturing a semiconductor package 100B of FIG. 24, a method for manufacturing a semiconductor package 100C of FIG. 26, a method for manufacturing a semiconductor package 100D of FIG. 28, and a method for manufacturing a semiconductor package 100E of FIG. 30.

FIG. 3 is a cross-sectional view showing an operation of modifying a glass wafer (or a glass panel) 131W using a laser L.

Referring to FIG. 3, the glass wafer 131W may be provided. The glass wafer 131W may include a glass core region 131R that becomes the glass core 131 after an individualization process is performed and the scribe lane SL around the glass core region 131R. The scribe lane SL may surround each of side surfaces of glass cores 131 (e.g., each of side surfaces of the glass core region 131R). In an embodiment, the glass wafer 131W may include borosilicate glass, quartz, or non-alkali glass.

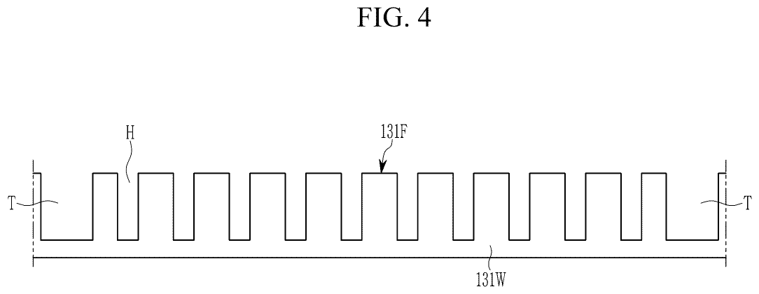

The glass wafer 131W may be modified by a laser beam from the laser L according to a pattern of a hole H (refer to FIG. 4) to be formed at the glass core region 131R and a pattern of a trench T (refer to FIG. 4) to be formed at the scribe lane SL. The laser beam from the laser L may form a first modification structure HM and a second modification structure TM within the glass wafer 131W without destroying the glass wafer 131W. The first modification structure HM may have a pattern shape for forming holes H. The second modification structure TM may have a pattern shape for forming trenches T. Each of the first modification structure HM and the second modification structure TM may have a shape recessed from a first surface 131F of the glass wafer 131W by a predetermined distance. The laser beam may modify a mesh structure of the glass wafer 131W into a linear chain structure. Modification of the glass wafer 131W may be performed along a beam axis of the laser beam. The laser beam may interact with the glass wafer 131W in a form of a pulse sequence. The pulse sequence may include single pulses. In an embodiment, the laser beam used for the modification may have a pulse width shorter than about 100 ns. In an embodiment, the laser beam used for the modification may have a pulse width shorter than about 1 fs.

FIG. 4 is a cross-sectional view showing an operation of etching the glass wafer 131W.

Referring to FIG. 4, an etching process may be performed on the glass wafer 131W, so that the holes H are formed at the glass core region 131R and the trench T is formed at the scribe lane SL. Each of the hole H and the trench T may have a shape recessed from the first surface 131F of the glass wafer 131W by a predetermined distance. In an embodiment, a process of etching the glass wafer 131W may be performed by isotropic wet etching. If the etching process is performed, portions of the glass wafer 131W having the mesh structure that are not modified into the linear chain structure may be hardly etched, and the first modification structure HM and the second modification structure TM of the glass wafer 131W that are modified into the linear chain structure by the laser beam may be quickly etched. Therefore, the etching may proceed along contours of the first modification structure HM and the second modification structure TM by the laser.

An inner surface of each of the hole H and the trench T formed through a two-operation process of the modification by the laser beam and the etching may have a different shape from a surface shape formed by performing cutting by the laser on the glass wafer 131W. In an embodiment, the inner surface of each of the hole H and the trench T may have a porous shape or a wavy shape. In an embodiment, the inner surface of each of the hole H and the trench T may have a shape in which a reduction portion and an extension portion are regularly or irregularly formed. In an embodiment, the inner surface of each of the hole H and the trench T may have a shape in which a reduction portion and an extension portion are continuously or discontinuously extended. The shapes of the embodiment described above may be ultrafine shapes, and the ultrafine shape of the inner surface of each of the hole H and the trench T may ensure excellent adhesive strength to a conductive material or a dielectric material formed inside each of the hole H and the trench T.

A surface roughness of the inner surface of each of the hole H and the trench T formed through the two-operation process of the modification by the laser beam and the etching may have a smaller value than a surface roughness of a surface formed by performing the cutting by the laser on the glass wafer 131W. In an embodiment, the surface roughness of the inner surface of each of the hole H and the trench T may be about 2 nm to about 40 nm. A low surface roughness of the inner surface of each of the hole H and the trench T may improve reliability of the through glass via (TGV) 132 formed by filling the conductive material within the hole H and reliability of the dummy structure 133 formed within the trench T.

If the glass wafer 131W is cut or drilled using the laser to form the hole H and the trench T at the glass wafer 131W, a microcrack may occur around a portion cut by the laser or a heat affected zone (HAZ) on which a stress acts may be generated so that a mechanical characteristic of the glass wafer 131W is degraded. According to the present disclosure, the hole H and the trench T may be formed at the glass wafer 131W by performing a composite process of the modification by the laser beam and the etching, so that a microcrack does not occur at the glass wafer 131W and a heat affected zone (HAZ) on which a stress acts is not generated.

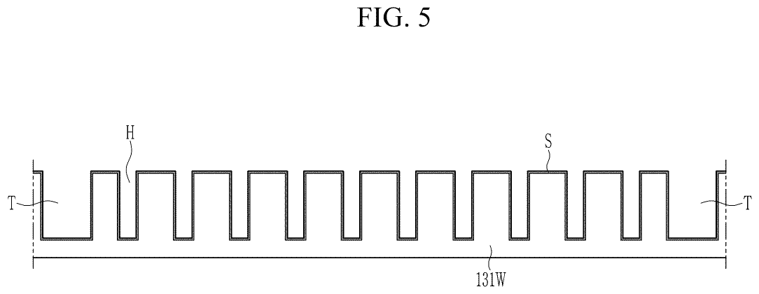

FIG. 5 is a cross-sectional view showing an operation of forming a seed metal layer S inside the holes H, inside the trenches T, and on the first surface 131F of the glass wafer 131W.

Referring to FIG. 5, the seed metal layer S may be conformally formed inside the holes H formed at the glass wafer 131W, inside the trenches T formed at the glass wafer 131W, and on the first surface 131F of the glass wafer 131W. In an embodiment, the seed metal layer S may include at least one of a first layer including titanium and a second layer including copper. In an embodiment, the seed metal layer S may include a conductive material capable of performing electrolytic plating. In an embodiment, the seed metal layer S may be formed by electroless plating. In an embodiment, a cleaning process or a metal catalyst activation pretreatment process may be performed prior to the electroless plating. In an embodiment, the seed metal layer S may be formed by sputtering.

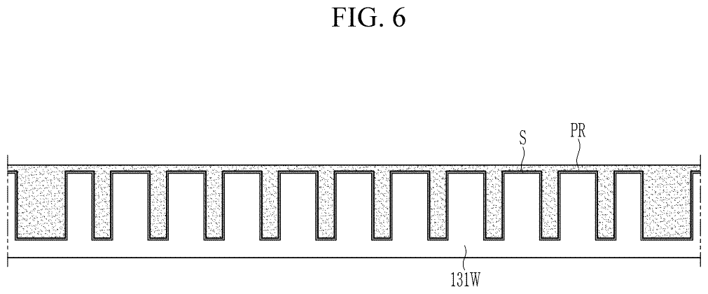

FIG. 6 is a cross-sectional view showing an operation of forming a photoresist PR on the seed metal layer S.

Referring to FIG. 6, the photoresist PR may fill the inside of the hole H, may fill the inside of the trench T, and may cover the seed metal layer S. In an embodiment, the photoresist PR may be formed through spin coating. In an embodiment, the photoresist PR may include an organic polymer resin including a photoactive material.

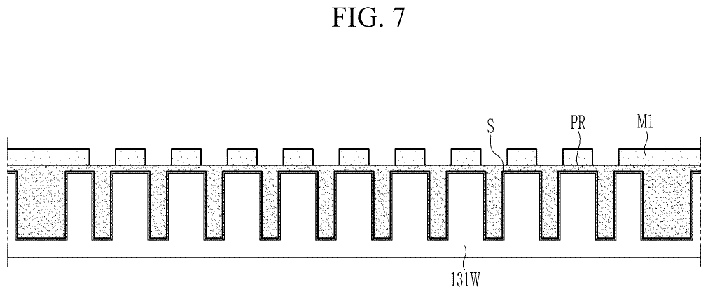

FIG. 7 is a cross-sectional view showing an operation of disposing a first photomask M1 on the photoresist PR.

Referring to FIG. 7, the first photomask M1 may be disposed on the photoresist PR.

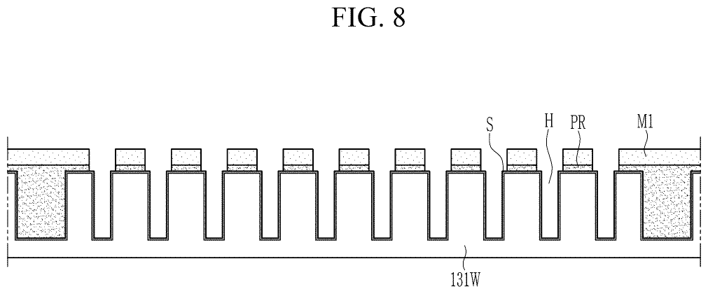

FIG. 8 is a cross-sectional view showing an operation of exposing and developing the photoresist PR.

Referring to FIG. 8, the photoresist PR may be exposed through the first photomask M1, and a region of the exposed photoresist PR may be developed and removed. Thereafter, a residue of the photoresist PR may be removed by performing a descum process. The seed metal layer S on the hole H and inside the hole H may be exposed at a region from which the photoresist PR is removed.

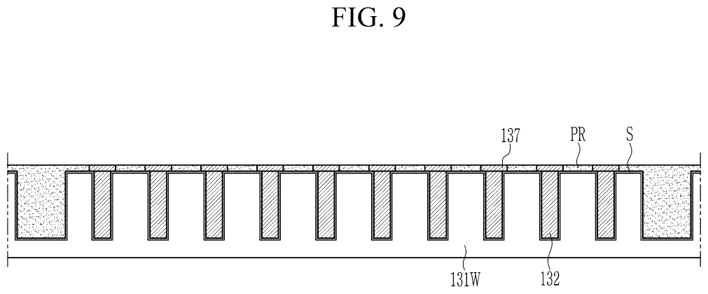

FIG. 9 is a cross-sectional view showing an operation of forming the through glass vias (TGVs) 132 inside the holes H.

Referring to FIG. 9, the first photomask M1 may be removed. Thereafter, the through glass vias (TGVs) 132 and the conductive pads 137 on the through glass vias (TGVs) 132 may be formed by filling the holes H with a conductive material. The through glass vias (TGVs) 132 and the conductive pads 137 may be formed by performing electrolytic plating on the seed metal layer S. In an embodiment, each of the through glass vias (TGVs) 132 and the conductive pads 137 may include a conductive material capable of performing electrolytic plating.

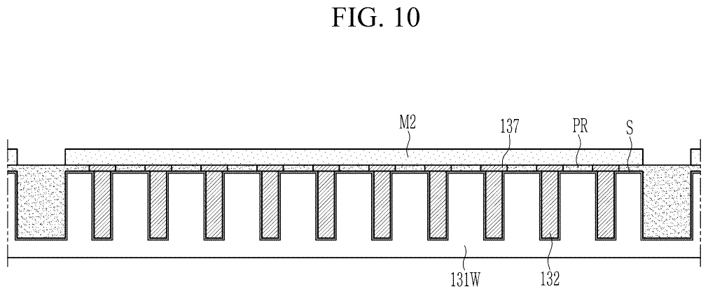

FIG. 10 is a cross-sectional view showing an operation of disposing a second photomask M2 on the photoresist PR.

Referring to FIG. 10, the second photomask M2 may be disposed on the photoresist PR.

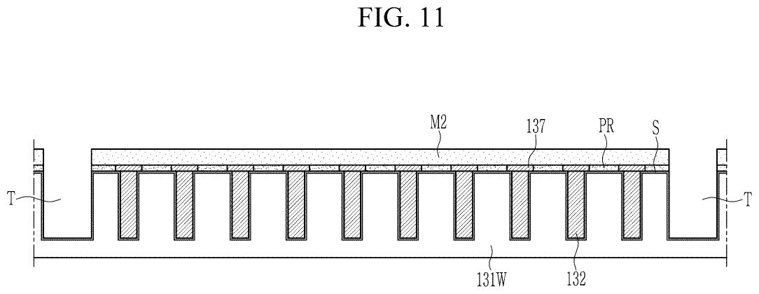

FIG. 11 is a cross-sectional view showing an operation of exposing and developing the photoresist PR.

Referring to FIG. 11, the photoresist PR may be exposed through the second photomask M2, and a region of the exposed photoresist PR may be developed and removed. Thereafter, a residue of the photoresist PR may be removed by performing a descum process. The seed metal layer S on the trench T and inside the trench T may be exposed at a region from which the photoresist PR is removed.

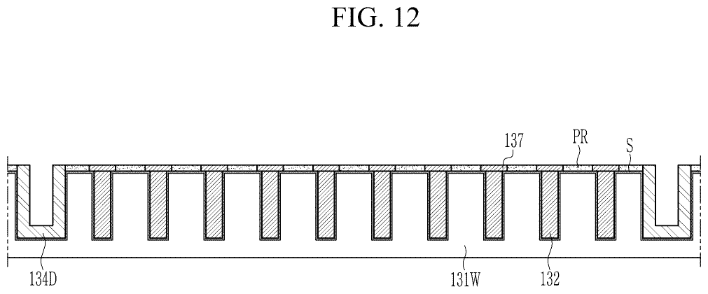

FIG. 12 is a cross-sectional view showing an operation of forming a conductive layer 134D inside the trench T.

Referring to FIG. 12, the second photomask M2 may be removed. Thereafter, the conductive layer 134D may be formed inside the trench T. The conductive layer 134D may be conformally formed along an inner surface of the trench T. The conductive layer 134D may become the first structure 134 of the dummy structure 133 through a subsequent process. The conductive layer 134D may be formed by performing electrolytic plating on the seed metal layer S. In an embodiment, the conductive layer 134D may include a conductive material capable of performing electrolytic plating.

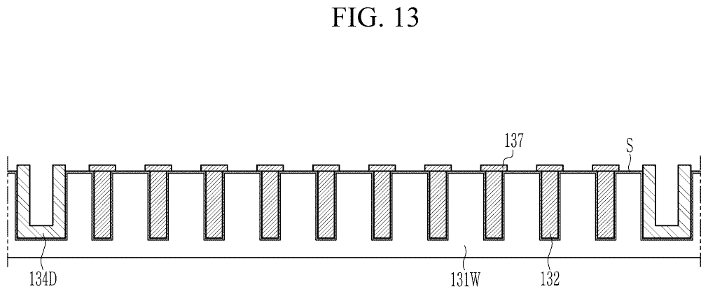

FIG. 13 is a cross-sectional view showing an operation of removing the photoresist PR.

Referring to FIG. 13, the photoresist PR may be removed. In an embodiment, the photoresist PR may be removed by at least one of etching, ashing, and stripping.

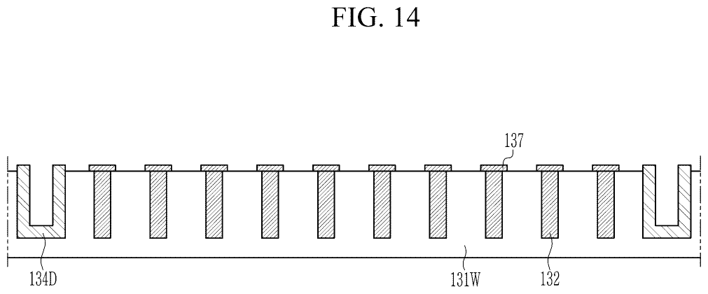

FIG. 14 is a cross-sectional view showing an operation of removing the seed metal layer S.

Referring to FIG. 14, the seed metal layer S exposed on the glass wafer 131W may be removed. The seed metal layer S may be removed by performing an etching process. Thereafter, a residue of the seed metal layer S may be removed by performing a descum process. In the subsequent drawings, the seed metal layer S between the glass wafer 131W and the through glass vias (TGVs) 132 and between the glass wafer 131W and the conductive layer 134D is not shown.

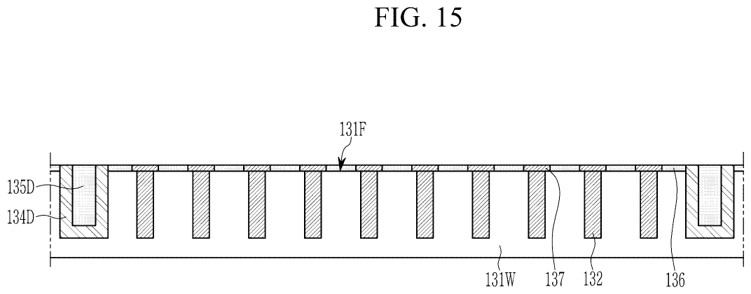

FIG. 15 is a cross-sectional view showing an operation of forming an insulating member 135D and the insulating layer 136.

Referring to FIG. 15, the insulating member 135D may be filled between conductive layers 134D within the trench T of the glass wafer 131W, and the insulating layer 136 may be formed on the first surface 131F of the glass wafer 131W. The insulating member 135D may fill an empty space within the trench T of the glass wafer 131W that is not filled by the conductive layer 134D. The insulating member 135D may become the second structure 135 of the dummy structure 133 through a subsequent process. The insulating layer 136 may be formed to surround the conductive pads 137. In an embodiment, the insulating member 135D and the insulating layer 136 may be formed by performing a chemical vapor deposition (CVD) process, a spin coating process, or a molding process. In an embodiment, the insulating member 135D may include a first organic dielectric. In an embodiment, the insulating layer 136 may include a first organic dielectric. In an embodiment, the first organic dielectric may include polyimide (PI), Ajinomoto Build-up Film (ABF), a photoimageable dielectric (PID), or an epoxy molding compound (EMC).

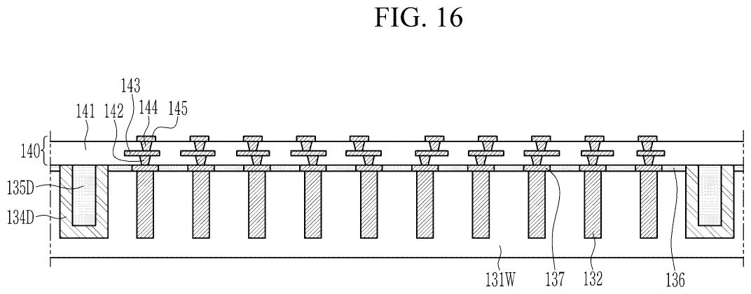

FIG. 16 is a cross-sectional view showing an operation of forming the upper redistribution structure 140 on the conductive layer 134D, the insulating member 135D, the insulating layer 136, and the conductive pads 137.

Referring to FIG. 16, the upper redistribution structure 140 may be formed on the conductive layer 134D, the insulating member 135D, the insulating layer 136, and the conductive pads 137. After the second dielectric 141 is formed on the conductive layer 134D, the insulating member 135D, the insulating layer 136, and the conductive pads 137, the second dielectric 141 may be selectively etched to form openings, and the first vias 142, the conductive lines 143, and the second vias 144 may be sequentially formed from below by filling the openings with a conductive material. After the second vias 144 are formed, a photoresist may be additionally deposited on the second vias 144 and the second dielectric 141, the photoresist may be selectively exposed and developed to form a photoresist pattern including openings, and the bonding pads 145 may be formed by filling the openings with a conductive material.

In an embodiment, the second dielectric 141 may be formed by performing a spin coating process. In an embodiment, the second dielectric 141 may include a second organic dielectric. In an embodiment, the second organic dielectric of the second dielectric 141 may be different from the first organic dielectric of the insulating member 135D. In an embodiment, the second organic dielectric of the second dielectric 141 may be different from the first organic dielectric of the insulating layer 136. In an embodiment, the second dielectric 141 may include a photoimageable dielectric (PID) used in a redistribution process. As an embodiment, the photoimageable dielectric (PID) may include a polyimide-based photosensitive polymer, a novolac-based photosensitive polymer, polybenzoxazole, a silicone-based polymer, an acrylate-based polymer, or an epoxy-based polymer. In an embodiment, a photoresist process and an etching process may be performed so that the second dielectric 141 is etched and openings are formed at the second dielectric 141. In an embodiment, the first vias 142, the conductive lines 143, the second vias 144, and the bonding pads 145 may be formed by performing a sputtering process or by performing an electrolytic plating process after a seed metal layer is formed. In an embodiment, each of the first vias 142, the conductive lines 143, the second vias 144, and the bonding pads 145 may include at least one of copper, aluminum, tungsten, nickel, gold, tin, titanium, and an alloy thereof.

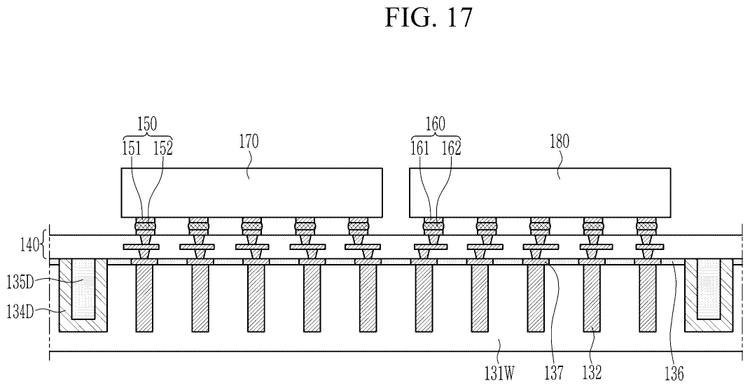

FIG. 17 is a cross-sectional view showing an operation of mounting the first semiconductor die 170 and the second semiconductor die 180 above the upper redistribution structure 140.

Referring to FIG. 17, the first semiconductor die 170 and the second semiconductor die 180 may be mounted above the upper redistribution structure 140. In an embodiment, the first semiconductor die 170 and the second semiconductor die 180 may be bonded above the upper redistribution structure 140 by performing a flip chip bonding process. Each first solder 152 of the first bump structures 150 connected to the first semiconductor die 170 may be bonded to a bonding pad 145 among the bonding pads 145 corresponding to each first solder 152. Each second solder 162 of the second bump structures 160 connected to the second semiconductor die 180 may be bonded to a bonding pad 145 among the bonding pads 145 corresponding to each second solder 162. The first semiconductor die 170 may be electrically connected to the upper redistribution structure 140 by the first bump structures 150, and the second semiconductor die 180 may be electrically connected to the upper redistribution structure 140 by the second bump structures 160.

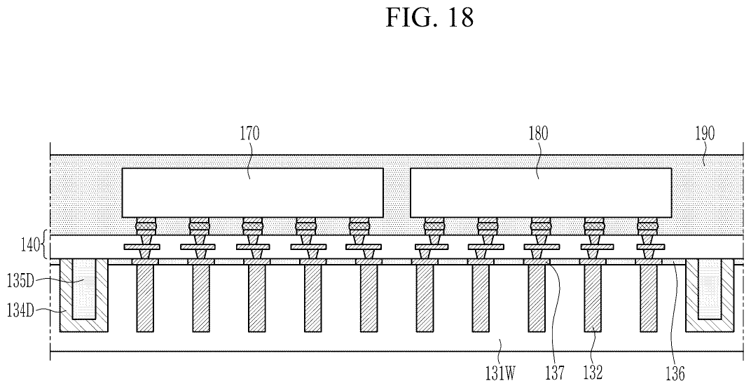

FIG. 18 is a cross-sectional view showing an operation of molding the first bump structures 150, the second bump structures 160, the first semiconductor die 170, and the second semiconductor die 180 on the upper redistribution structure 140.

Referring to FIG. 18, the first bump structures 150, the second bump structures 160, the first semiconductor die 170, and the second semiconductor die 180 may be covered by the molding material 190 on the upper redistribution structure 140. As an embodiment, a process of molding the first bump structures 150, the second bump structures 160, the first semiconductor die 170, and the second semiconductor die 180 with the molding material 190 may include a compression molding or transfer molding process. In an embodiment, the molding material 190 may include an epoxy molding compound (EMC).

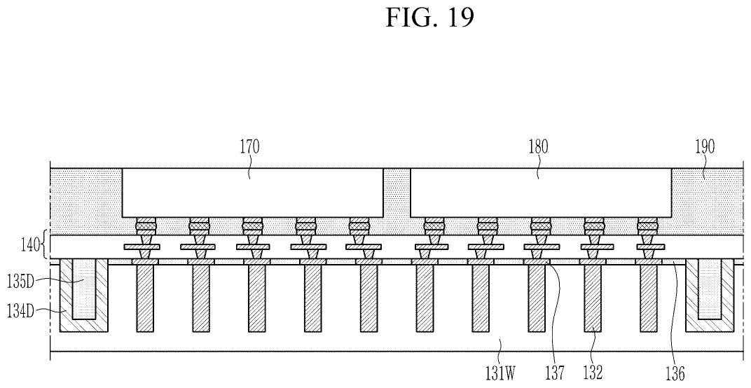

FIG. 19 is a cross-sectional view showing an operation of planarizing the molding material 190.

Referring to FIG. 19, a planarization process may be performed to level an upper surface of the molding material 190. In an embodiment, the planarization process may perform chemical mechanical polishing (CMP). After the CMP process is performed, an upper surface of the first semiconductor die 170 and an upper surface of the second semiconductor die 180 may be exposed to the outside.

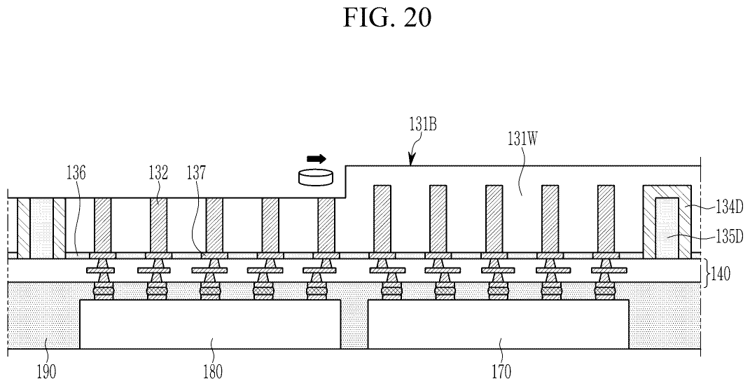

FIG. 20 is a cross-sectional view showing an operation of thinning a second surface 131B of the glass wafer 131W.

Referring to FIG. 20, the second surface 131B of the glass wafer 131W may be thinned. The second surface 131B of the glass wafer 131W may be an opposite surface of the first surface 131F of the glass wafer 131W. In an embodiment, the thinning process may be performed by grinding. After the thinning process, the dummy structure 133 and the through glass vias (TGVs) 132 may be exposed.

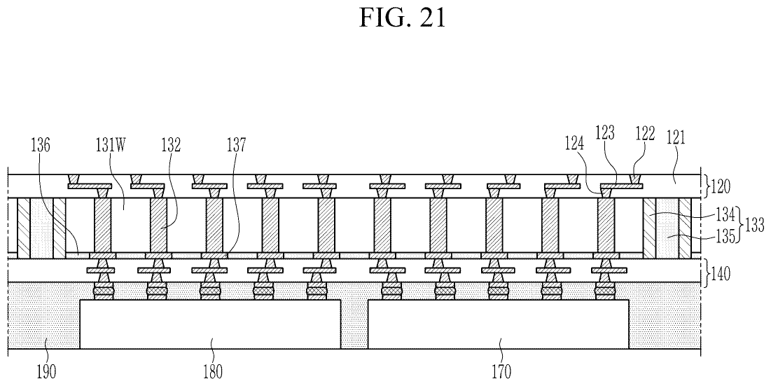

FIG. 21 is a cross-sectional view showing an operation of forming the lower redistribution structure 120 on the thinned second surface 131B of the glass wafer 131W.

Referring to FIG. 21, the lower redistribution structure 120 may be formed on the exposed dummy structure 133, on the exposed through glass vias (TGVs) 132, and on the glass wafer 131W. After the first dielectric 121 is formed on the exposed dummy structure 133, on the exposed through glass vias (TGVs) 132, and on the glass wafer 131W, the first dielectric 121 may be selectively etched to form openings, and the second vias 124, the conductive lines 123, and the first vias 122 may be sequentially formed from below by filling the openings with a conductive material.

Because the lower redistribution structure 120 is formed later than the upper redistribution structure 140, in the semiconductor package 100A that is a final product, each of the first vias 122 and the second vias 124 of the lower redistribution structure 120 may have a shape in which a width in a horizontal direction thereof decreases from the bottom to the top. In an embodiment, the first dielectric 121 may be formed by performing a spin coating process. In an embodiment, the first dielectric 121 may include a second organic dielectric. In an embodiment, the second organic dielectric of the first dielectric 121 may be different from the first organic dielectric of the insulating member 135D. In an embodiment, the second organic dielectric of the first dielectric 121 may be different from the first organic dielectric of the insulating layer 136. In an embodiment, the first dielectric 121 may include a photoimageable dielectric (PID) used in a redistribution process. As an embodiment, the photoimageable dielectric (PID) may include a polyimide-based photosensitive polymer, a novolac-based photosensitive polymer, polybenzoxazole, a silicone-based polymer, an acrylate-based polymer, or an epoxy-based polymer. In an embodiment, a photoresist process and an etching process may be performed so that the first dielectric 121 is etched and openings are formed at the first dielectric 121. In an embodiment, the first vias 122, the conductive lines 123, and the second vias 124 may be formed by performing a sputtering process or by performing an electrolytic plating process after a seed metal layer is formed. In an embodiment, each of the first vias 122, the conductive lines 123, and the second vias 124 may include at least one of copper, aluminum, tungsten, nickel, gold, tin, titanium, and an alloy thereof.

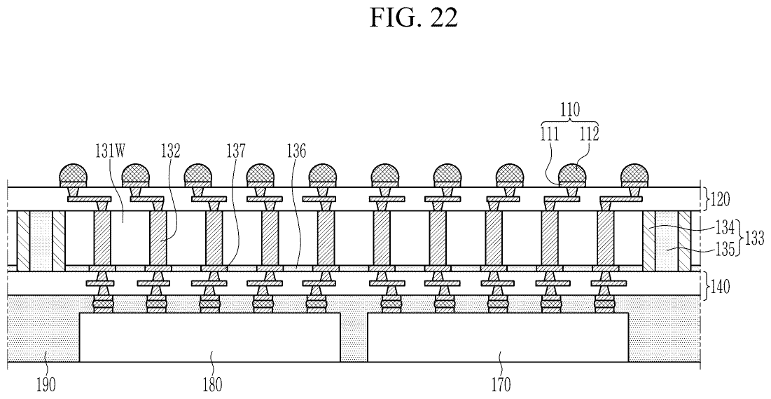

FIG. 22 is a cross-sectional view showing an operation of forming external connection structures 110 above the upper redistribution structure 140.

Referring to FIG. 22, the external connection structure 110 may be formed above the upper redistribution structure 140. Each of the connection pads 111 may be formed on a first via 122 among the first vias 122 of the upper redistribution structure 140 corresponding to each of the connection pads 111. In an embodiment, the connection pad 111 may be formed by performing a sputtering process or by performing an electrolytic plating process after a seed metal layer is formed. In an embodiment, the connection pad 111 may include at least one of copper, nickel, zinc, gold, silver, platinum, palladium, chromium, titanium, and an alloy thereof. Thereafter, the external connection member 112 may be formed on each of the connection pads 111. In an embodiment, the external connection member 112 may include at least one of tin, silver, lead, nickel, copper, and an alloy thereof.

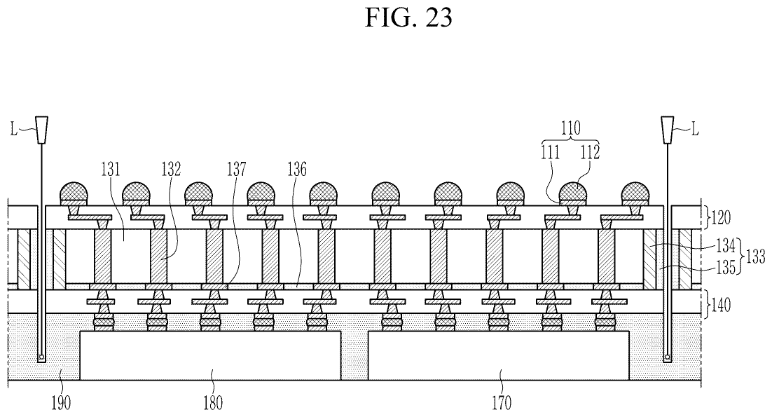

FIG. 23 is a cross-sectional view showing an operation of singulating the reconstituted glass wafer 131W.

Referring to FIG. 23, an individual semiconductor package 100A may be formed by singulating the molding material 190, the upper redistribution structure 140, the second structure 135, and the lower redistribution structure 120. In an embodiment, the singulation process may be performed by cutting using the laser L.

If the glass wafer 131W is cut or drilled using the laser, a microcrack may occur around a portion cut by the laser or a heat affected zone (HAZ) on which a stress acts may be generated due to high brittleness of the glass material. According to the present disclosure, the dummy structure 133 including at least one of a metal and an organic dielectric having less brittleness than that of the glass material may be formed along the scribe lane SL, so that the dummy structure 133 is cut when the cutting is performed along the scribe lane SL. Thus, the microcrack may not occur around the portion cut by the laser and the heat affected zone (HAZ) on which the stress acts may not be generated. In an embodiment, the glass core 131 may have a first brittleness, the second structure 135 of the dummy structure 133 may have a second brittleness, and the first brittleness may be greater than the second brittleness.

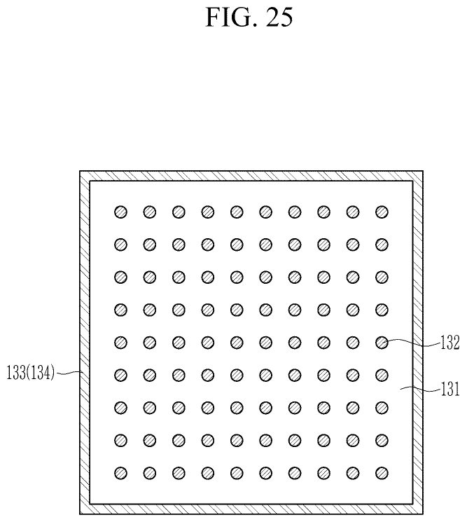

FIG. 24 is a cross-sectional view showing the semiconductor package 100B of an embodiment. FIG. 25 is a plan view of a core layer 130 of the semiconductor package 100B of FIG. 24 cut along a line B-B.

Referring to FIG. 24 and FIG. 25, the core layer 130 of the semiconductor package 100B may include a dummy structure 133. The dummy structure 133 may be a first structure 134. The dummy structure 133 may include a metal. The dummy structure 133 may include inner side surfaces and outer side surfaces. The inner side surfaces of the dummy structure 133 may cover side surfaces of a glass core 131. The outer side surfaces of the dummy structure 133 may be exposed to the outside. An upper surface of the dummy structure 133 may have the same level as a level of an upper surface of an insulating layer 136 and levels of upper surfaces of conductive pads 137. A lower surface of the dummy structure 133 may have the same level as that of a lower surface of the glass core 131. The dummy structure 133 may conformally extend along side surfaces of the glass core 131. The dummy structure 133 may continuously extend along the side surfaces of the glass core 131. The dummy structure 133 including the metal may serve to limit and/or prevent a microcrack from occurring around a cutting portion when the dummy structure 133 is cut and to limit and/or prevent moisture from penetrating into the glass core 131. In addition, the dummy structure 133 including the metal may discharge heat generated within the semiconductor package 100B to the outside through the dummy structure 133, so that a heat dissipation characteristic of the semiconductor package 100B is improved. In an embodiment, the glass core 131 may have a first brittleness, the dummy structure 133 may have a second brittleness, and the first brittleness may be greater than the second brittleness.

The contents described for the semiconductor package 100A of FIG. 1 and FIG. 2 may be applied to contents other than those described for the semiconductor package 100B of FIG. 24 and FIG. 25.

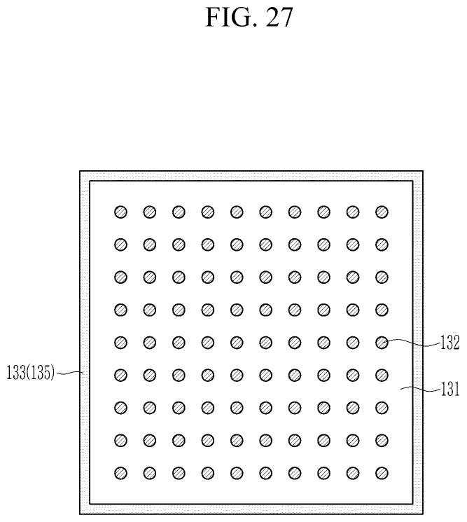

FIG. 26 is a cross-sectional view of the semiconductor package 100C of an embodiment. FIG. 27 is a plan view of a core layer 130 of the semiconductor package 100C of FIG. 26 cut along a line C-C.

Referring to FIG. 26 and FIG. 27, the core layer 130 of the semiconductor package 100C may include a dummy structure 133. The dummy structure 133 may be a second structure 135. The dummy structure 133 may include a first organic dielectric. In an embodiment, the first organic dielectric may include polyimide (PI), Ajinomoto Build-up Film (ABF), a photoimageable dielectric (PID), or an epoxy molding compound (EMC). The dummy structure 133 may include inner side surfaces and outer side surfaces. The inner side surfaces of the dummy structure 133 may cover side surfaces of a glass core 131. The outer side surfaces of the dummy structure 133 may be exposed to the outside. An upper surface of the dummy structure 133 may have the same level as a level of an upper surface of an insulating layer 136 and levels of upper surfaces of conductive pads 137. A lower surface of the dummy structure 133 may have the same level as that of a lower surface of the glass core 131. The dummy structure 133 may conformally extend along side surfaces of the glass core 131. The dummy structure 133 may continuously extend along the side surfaces of the glass core 131. The dummy structure 133 including the first organic dielectric may serve to limit and/or prevent a microcrack from occurring around a cutting portion when the dummy structure 133 is cut. In an embodiment, the glass core 131 may have a first brittleness, the dummy structure 133 may have a second brittleness, and the first brittleness may be greater than the second brittleness.

The contents described for the semiconductor package 100A of FIG. 1 and FIG. 2 may be applied to contents other than those described for the semiconductor package 100C of FIG. 26 and FIG. 27.

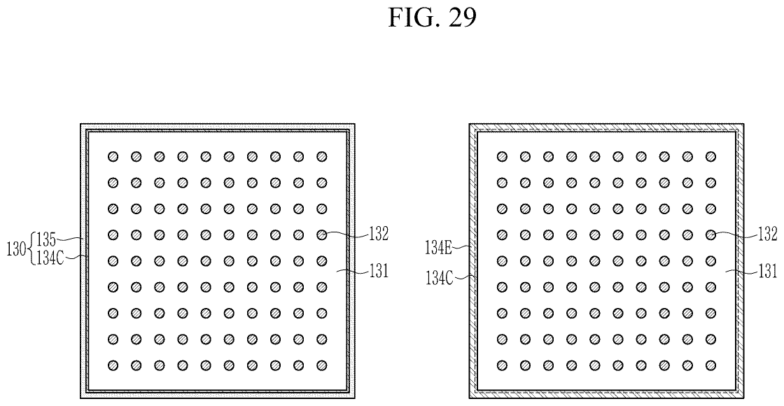

FIG. 28 is a cross-sectional view showing the semiconductor package 100D of an embodiment. FIG. 29 is a plan view of a core layer of the semiconductor package 100D of FIG. 28 cut along lines D-D and E-E.

Referring to FIG. 28, the core layer 130 of the semiconductor package 100D may include a dummy structure 133. The dummy structure 133 may include a first structure 134 and a second structure 135. The first structure 134 may include a cover portion 134C and an extension portion 134E. The cover portion 134C may cover side surfaces of a glass core 131. The extension portion 134E may extend from the cover portion 134C in an opposite direction of the glass core 131. The extension portion 134E may be exposed to the outside. The first structure 134 may include a metal. An upper surface of the cover portion 134C may have the same level as a level of an upper surface of an insulating layer 136 and levels of upper surfaces of conductive pads 137. A lower surface of the first structure 134 may have the same level as that of a lower surface of the glass core 131. A lower surface of the extension portion 134E may have the same level as that of a lower surface of the cover portion 134C, and the extension portion 134E may have a height H1 in a vertical direction corresponding to at least a portion of a height H2 in the vertical direction of the cover portion 134C.

The second structure 135 may be disposed on the extension portion 134E. The second structure 135 may include a first organic dielectric. In an embodiment, the first organic dielectric may include polyimide (PI), Ajinomoto Build-up Film (ABF), a photoimageable dielectric (PID), or an epoxy molding compound (EMC). The second structure 135 may be exposed to the outside of the semiconductor package 100D. An upper surface of the second structure 135 may have the same level as the level of the upper surface of the insulating layer 136 and the levels of the upper surfaces of the conductive pads 137.

Referring to FIG. 29, the cover portion 134C may conformally extend along side surfaces of the glass core 131. The cover portion 134C may continuously extend along the side surfaces of the glass core 131. The extension portion 134E may conformally extend along side surfaces of the cover portion 134C. The extension portion 134E may continuously extend along the side surfaces of the cover portion 134C. The first structure 134 may include a metal, and the first structure 134 including the metal may serve to limit and/or prevent moisture from penetrating into the glass core 131. Additionally, the extension portion 134E including a metal may continuously extend from the cover portion 134C including a metal. Accordingly, heat generated within the semiconductor package 100D may be dissipated to the outside through the extension portion 134E and the cover portion 134C, so that a heat dissipation characteristic of the semiconductor package 100D is improved. The second structure 135 may conformally extend along the side surfaces of the cover portion 134C on the extension portion 134E. The second structure 135 may continuously extend along the side surfaces of the cover portion 134C on the extension portion 134E. The second structure 135 may include a first organic dielectric, and the second structure 135 including the first organic dielectric may serve to limit and/or prevent a microcrack from occurring around a cutting portion when the second structure 135 is cut.

The contents described for the semiconductor package 100A of FIG. 1 and FIG. 2 may be applied to contents other than those described for the semiconductor package 100D of FIG. 28 and FIG. 29.

FIG. 30 is a cross-sectional view showing the semiconductor package 100E of an embodiment.

Referring to FIG. 30, a core layer 130 of the semiconductor package 100E may include a glass core 131, through glass vias (TGVs) 132, and a dummy structure 133. Each of the through glass vias (TGVs) 132 may be disposed between a second via 124 among second vias 124 of a lower redistribution structure 120 corresponding to each of the through glass vias (TGVs) 132 and a first via 142 among first vias 142 of an upper redistribution structure 140 corresponding to each of the through glass vias (TGVs) 132. Each of the through glass vias (TGVs) 132 may electrically connect the first via 142 among the first vias 142 of the upper redistribution structure 140 corresponding to each of the through glass vias (TGVs) 132 to the second via 124 among the second vias 124 of the lower redistribution structure 120 corresponding to each of the through glass vias (TGVs) 132.

The dummy structure 133 may be disposed next to the glass core 131. The dummy structure 133 may be disposed around the glass core 131. The dummy structure 133 may surround side surfaces of the glass core 131. The dummy structure 133 may cover and protect the side surfaces of the glass core 131. An upper surface of the dummy structure 133 may have the same level as that of an upper surface of the glass core 131. A lower surface of the dummy structure 133 may have the same level as that of a lower surface of the glass core 131.

The upper redistribution structure 140 may be disposed on the core layer 130. The upper redistribution structure 140 may cover the upper surface of the glass core 131, upper surfaces of the through glass vias (TGVs) 132, and the upper surface of the dummy structure 133.

The contents described for the semiconductor package 100A of FIG. 1 and FIG. 2 may be applied to contents other than those described for the semiconductor package 100E of FIG. 30.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While this disclosure has been described in connection with what is presently considered to be practical embodiments, it should be understood that the disclosure is not limited to the disclosed embodiments, but, on the contrary, is intended to cover various modifications and equivalent arrangements included within the spirit and scope of the appended claims.

What is claimed is:

1. A glass substrate comprising:
a first redistribution structure;
a core layer on the first redistribution structure,
the core layer including a glass core and a dummy structure surrounding side surfaces of the glass core, and the dummy structure including a metal material, an organic material, or both the metal material and the organic material; and
a second redistribution structure on the core layer.

2. The glass substrate of claim 1, wherein the dummy structure covers the side surfaces of the glass core.

3. The glass substrate of claim 1, wherein the dummy structure conformally extends along the side surfaces of the glass core.

4. The glass substrate of claim 1, wherein the dummy structure is exposed to an outside environment.

5. The glass substrate of claim 1, wherein the second redistribution structure covers an upper surface of the glass core and an upper surface of the dummy structure.

6. The glass substrate of claim 1, wherein
the glass core has a first brittleness,
the dummy structure has a second brittleness, and
the first brittleness is greater than the second brittleness.

7. The glass substrate of claim 1, wherein
the dummy structure comprises a first structure including the metal material and a second structure including the organic material,
inner side surfaces of the first structure cover the side surfaces of the glass core, and
the second structure covers outer side surfaces of the first structure.

8. The glass substrate of claim 1, wherein
the dummy structure includes a first structure including the metal material,
a cover portion of the first structure covers the side surfaces of the glass core, and
an extension portion of the first structure extends from the cover portion in an opposite direction of the glass core.

9. The glass substrate of claim 8, wherein
the dummy structure further includes a second structure on the extension portion, and
the second structure includes the organic material.

10. The glass substrate of claim 1, wherein the dummy structure has a quadrangular frame shape on a plane.

11. A semiconductor package comprising:
a glass substrate including a first redistribution structure, a core layer on the first redistribution structure, and a second redistribution structure on the core layer;
a plurality of semiconductor dies on the glass substrate; and
a molding material covering the plurality of semiconductor dies on the glass substrate, wherein
the core layer includes a glass core, a plurality of through glass vias penetrating the glass core, and a dummy structure surrounding side surfaces of the glass core, and
the dummy structure includes a metal, a first organic dielectric, or both the metal and the first organic dielectric.

12. The semiconductor package of claim 11, wherein the first organic dielectric includes polyimide (PI), Ajinomoto Build-up Film (ABF), a photoimageable dielectric (PID), or an epoxy molding compound (EMC).

13. The semiconductor package of claim 11, wherein the core layer further comprises an insulating layer between the glass core and the second redistribution structure.

14. The semiconductor package of claim 13, wherein
the core layer further comprises a plurality of conductive pads between the glass core and the second redistribution structure, and
the plurality of conductive pads penetrate the insulating layer and are electrically connected to the plurality of through glass vias and the second redistribution structure.

15. The semiconductor package of claim 13, wherein the insulating layer includes the first organic dielectric.

16. The semiconductor package of claim 11, wherein
the second redistribution structure includes a second organic dielectric, and
the second organic dielectric is different from the first organic dielectric.

17. The semiconductor package of claim 16, wherein the second organic dielectric includes a photoimageable dielectric (PID).

18. The semiconductor package of claim 11, wherein the dummy structure is electrically separated from the plurality of semiconductor dies.

19. A method for manufacturing a semiconductor package, comprising:
providing a glass wafer including a plurality of glass cores and a scribe lane surrounding side surfaces of each of the plurality of glass cores;
forming a plurality of holes recessed from a first surface of the glass wafer within each of the plurality of glass cores and forming a trench recessed from the first surface of the glass wafer along the scribe lane;
forming a plurality of through glass vias, the forming the plurality of through glass vias including filling the plurality of holes with a conductive material;
forming a dummy structure in the trench, the dummy structure including a metal, an organic dielectric, or both the metal and the organic dielectric;
forming an upper redistribution structure on the first surface of the glass wafer;
mounting a plurality of semiconductor dies on the upper redistribution structure;
providing a molding material on the plurality of semiconductor dies on the upper redistribution structure;
thinning a second surface of the glass wafer to expose the plurality of through glass vias and the dummy structure, wherein the second surface of the glass wafer is opposite the first surface of the glass wafer;
forming a lower redistribution structure on the second surface of the glass wafer after the thinning the second surface of the glass wafer; and
forming an individual semiconductor package by cutting the molding material, the upper redistribution structure, the dummy structure, and the lower redistribution structure.

20. The method of claim 19, wherein the forming of the plurality of holes recessed from the first surface of the glass wafer within each of the plurality of glass cores and the forming of the trench recessed from the first surface of the glass wafer along the scribe lane comprises:
modifying the glass wafer with a laser according to a pattern of the plurality of holes to be formed and a pattern of the trench to be formed; and
performing etching on the glass wafer to form the plurality of holes and the trench.
